(19) United States
(12) Patent Application Publication
(10) Pub. No.: US 2010/0155962 A1
(43) Pub. Date: Jun. 24, 2010

(54) SEMICONDUCTOR DEVICE AND METHOD FOR FABRICATING THE SAME

(75) Inventors: Daisuke INOUE, Osaka (JP); Takahiro Nakano, Kyoto (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/714,192

(22) Filed: Feb. 26, 2010

Related U.S. Application Data
(63) Continuation of application No. PCT/JP2009/003534, filed on Jul. 27, 2008.

(30) Foreign Application Priority Data
Nov. 27, 2008 (JP) 2008-302389

(51) Int. Cl. H01L 23/48; H01L 21/768

(52) U.S. Cl. 257/774; 438/667; 257/773; 257/E21.576; 257/E23.011

(57) ABSTRACT

A semiconductor device includes a semiconductor substrate, a diffusion region provided on a surface portion of a first surface of the semiconductor substrate, a first line provided on the first surface of the semiconductor substrate, a through-hole penetrating the semiconductor substrate in the thickness direction, and a through-hole electrode provided in the through-hole, and contacting a rear surface of the first line and extending to a second surface opposite the first surface of the semiconductor substrate. The semiconductor device further includes a recess provided on the second surface of the semiconductor substrate and a second line provided in the recess and electrically connected to the through-hole electrode.

### CROSS-REFERENCE TO RELATED APPLICATION

This is a continuation of PCT International Application PCT/JP2009/003534 filed on Jul. 27, 2009, which claims priority to Japanese Patent Application No. 2008-302389 filed on Nov. 27, 2008. The disclosures of these applications including the specifications, the drawings, and the claims are hereby incorporated by reference in its entirety.

### BACKGROUND

A semiconductor device is fabricated such that process treatments such as diffusion and wiring are performed on a semiconductor wafer, thereby forming semiconductor elements, then dicing and packaging are performed in order that connection can be made to an external circuit. Many such semiconductor devices are used in electronic devices.

Of semiconductor devices, semiconductor devices employing “vertical” semiconductor elements, such as power MOSFETs (Metal-Oxide-Semiconductor Field-Effect Transistors), power transistors, and diodes, which handle relatively high currents, have been difficult to miniaturize. In cases of vertical semiconductor elements, this is because electric connections are made by die-bonding and wire-bonding from both the front side and the rear side of semiconductor elements, and because semiconductor devices are large in size after packaging due to generally used plastic packages and ceramic packages.

In this regard, in recent years, wafer-level CSP (Chip Size Package) technology has been receiving increasing attention. This is a technology to ensure electric connection by forming through-hole electrodes and by performing redistribution in an assembly process in a wafer state.

FIG. 5 schematically illustrates a cross-sectional view of a semiconductor device having a wafer-level CSP configuration described in Japanese Unexamined Patent Application Publication (Translation of PCT Application) No. 2003-530695.

As shown in FIG. 5, a semiconductor device 100 applied in a power MOSFET includes a semiconductor element 101, and a support substrate 103, which is attached to the entire rear surface (the upper surface as shown in the figure) of the semiconductor element 101 using a conductive adhesion layer 102. A first surface (the lower surface as shown in the figure) of the semiconductor element 101 has a gate/source layer 104 formed thereon, while in the other surface (a second surface) side, a drain layer 105 is formed.

In addition, through-hole electrodes 106 penetrating the semiconductor element 101 from the first surface to the second surface in the rear side are formed. On the first surface of the semiconductor element 101, metal line segments 107a for connection to the gate/source layer 104, and metal line segments 107b for connection to the through-hole electrodes 106 are formed. Also, formed is an insulation layer 108, which covers the first surface of the semiconductor element 101 and has openings selectively over the metal line segments 107a and the metal line segments 107b. In these openings, external electrodes 109a and external electrodes 109b are formed on the metal line segments 107a and the metal line segments 107b, respectively.

Here, the gate/source layer 104 is electrically connected to the external electrodes 109a through the metal line segments 107a. Also, the drain layer 105 and the conductive adhesion layer 102 are electrically connected to each other, and the through-hole electrodes 106 are electrically connected to the external electrodes 109b through the metal line segments 107b. As a result, the drain layer 105 is electrically connected to the external electrodes 109b through the adhesion layer 102, the through-hole electrodes 106, and the metal line segments 107b.

Due to this configuration, even though the semiconductor element 101 itself has a vertical configuration where the gate/source layer 104 is formed on the first surface side, and the drain layer 105 is formed on the second surface side, electric connections of the gate/source layer 104 with the external electrodes 109a and the drain layer 105 with the external electrodes 109b, respectively, allow electrical signals to be output through the external electrodes formed on a same surface. Thus, this kind of semiconductor devices are preferred for miniaturization and thickness reduction, as compared to semiconductor devices such as in plastic packages or in ceramic packages.

### SUMMARY

The semiconductor device with respect to the background art described above has a thick drain layer because the thickness of the semiconductor element is uniform. Since this leads to a large drain resistance, it has been difficult to handle high currents.

In addition, when consideration is given to thickness reduction of the drain layer of the above-mentioned semiconductor device, thinning processes such as grinding, lapping, and polishing need to be performed on the entire second surface of the Si substrate, thereby causing the entire Si substrate to be thinner. As a result, non-uniformity occurs in stress balance between the first and the second surfaces of the Si substrate, and problems such as warpage and reduced bending strength occur.

As such, in the above-mentioned semiconductor device, a support substrate is attached on the second surface of the Si substrate for reinforcement. However, this structure has many disadvantages such as an increase in the thickness of a semiconductor device, and an increase in costs due to an increase in the number of fabrication steps as well as material costs.

In view of the foregoing, a semiconductor device which can handle high currents and can achieve thickness reduction while obtaining a desired strength will be described below.

A semiconductor device in accordance with the present disclosure includes a semiconductor substrate having a first surface and a second surface opposite the first surface, a diffusion region provided on a surface portion of the first surface, a first line provided on the first surface, a through-hole penetrating the semiconductor substrate in the thickness direction, a through-hole electrode provided in the through-hole, and contacting a rear surface of the first line and extending to the second surface, a recess provided on the second surface, and a second line provided in the recess and electrically connected to the through-hole electrode; and a part of the first line is electrically connected to the diffusion region.

The semiconductor device may include an electrode portion provided on the diffusion region.

In addition, it is preferred to include filling layers filling the through-hole and the recess.

With such a semiconductor device, since the semiconductor substrate is locally thinned in a portion where the diffusion region is formed, resistance while the circuit is operating is reduced with respect to an element in a vertical configuration. This is achieved by forming a recess on the semiconductor substrate from the second surface (the surface opposite the first surface) side, which corresponds to the diffusion region formed on the first surface of the semiconductor substrate. Thus, a maximum current consumption of the semiconductor device can be increased.

Furthermore, the above-mentioned semiconductor device provides advantages in miniaturization and thickness reduction for the following reasons: Firstly, through the through-hole electrode, and the first and the second lines, etc., electrical signals within the vertical structure is electrically output to a same surface (the first surface). Secondly, due to a structure in which the semiconductor substrate is locally thinned, bending strength is higher as compared to a structure in which the semiconductor substrate is uniformly thinned. If a filling layer which fills the recess is also provided, bending strength is much higher. Therefore, a support substrate is no longer required.

As described above, the above-mentioned semiconductor device is advantageous in both electrical properties such as the maximum current consumption and bending strength, and a support substrate for strength improvement is not required. As a result, the semiconductor device is not only advantageous in miniaturization and thickness reduction thereof, but also allows for reduction of the number of fabrication steps for attaching the support substrate as well as cost reduction in material costs, etc. Note that the filling layers may be made of resin or metal. In addition, it is preferred that the first line be electrically connected to the diffusion region through the electrode portion.

Moreover, it is preferred that the recess be formed so as to avoid contact with a peripheral edge of the semiconductor substrate.

That is, it is preferable that the recess be formed in a way such that a portion having a box shape, etc., is hollowed out from the second surface of the semiconductor substrate, and that the recess not reach any lateral surface of the semiconductor substrate. Such a configuration is effective in preventing a reduction of the bending strength of the semiconductor substrate caused by the recess.

It is preferred that the recess be formed in the opposite side of the diffusion region. With this configuration, an effect to reduce the thickness of the semiconductor substrate in a portion of the diffusion region is achieved more reliably.

Moreover, the through-hole is preferred to be disposed in the recess.

With this configuration, the through-hole can be shallower than when disposed outside the recess. As such, processability of the through-hole is improved, and filling capability of the through-hole by the filling layer is also improved, thereby preventing problems such as void and unfilled condition from occurring. In addition, since the recess is formed so as to include the portion of the through-hole, the area of the recess becomes larger. As a result, filling capability with respect to filling the recess is also improved, and the amount to fill the filling layers becomes larger, thereby contributing to improvement of the strength of the semiconductor substrate.

Also, it is preferred that the semiconductor device include a first insulation film covering the first surface of the semiconductor substrate, and a second insulation film covering the second surface of the semiconductor substrate, a sidewall of the through-hole, and a sidewall and a bottom of the recess; and the fist insulation film has an opening selectively provided over the diffusion region, and the second insulation film has an opening selectively provided over the bottom of the recess.

With this configuration, leakage currents from the diffusion region (e.g., a leakage current from the diffusion region to the through-hole electrode) can be prevented, and as a result, a current can flow efficiently and sequentially from the diffusion region through a portion of the semiconductor substrate thinned by the recess, the bottom of the recess, and to the second line.

The semiconductor device may include a first insulation resin layer provided on the first surface of the semiconductor substrate so as to cover the first line, and the first insulation resin layer may have openings selectively provided over the first line.

In addition, the openings provided in the first insulation resin layer may include external electrodes which are electrically connected to the first line.

Also, the semiconductor device may include a second insulation resin layer on the second surface of the semiconductor substrate.

The second insulation resin layer is preferred to be formed of a same resin material as that of the filling layers. This will allow the second insulation resin layer and the filling layers to be formed in a same step, thereby reducing the number of steps and the costs of fabrication.

In addition, the second insulation resin layer is preferred to be formed of a light-blocking resin.

This will prevent a photocurrent from being induced by light excitation on a semiconductor substrate having a photoelectric effect, thereby preventing a malfunction of the semiconductor substrate.

Next, a method for fabricating a semiconductor device includes acts of (a) preparing a semiconductor substrate including a diffusion region provided on a surface portion of a first surface, (b) forming a first line on the first surface, (c) forming a through-hole penetrating the semiconductor substrate in the thickness direction, (d) forming a through-hole electrode, in the through-hole, extending from a rear surface of the first line to a second surface of the semiconductor substrate, (e) forming a recess on the second surface, and (f) forming a second line, in the recess, electrically connected to the through-hole electrode; and a part of the first line is electrically connected to the diffusion region.

It is preferred that, after the act (d) and the act (f), the method include an act of (g) forming filling layers filling the through-hole and the recess.

With such a method for fabricating a semiconductor device, a semiconductor device in which the semiconductor substrate is thinned in a portion of the diffusion region in a vertical configuration can be fabricated. That is, a semiconductor device with a configuration and advantages described above can be fabricated.

In addition, it is preferred that the act (c) be performed after the act (e), and in the act (c), the through-hole be formed in the recess.

Alternatively, it is preferred that the act (c) be performed before the act (e), and in the act (e), the recess is formed so as to include the through-hole.

With either method, a configuration where the through-hole is formed in the recess can be obtained. The advantage of a semiconductor device having such a configuration is as described above.

It is also preferred that the act (d) and the act (f) be performed substantially concurrently. According to this, the through-hole electrode and the second line can be formed in a same step, thereby reducing the number of fabrication steps.

Furthermore, it is preferred to further include an act of forming a first insulation film which covers the first surface of the semiconductor substrate, and selectively providing an opening over the diffusion region in the first insulation film; and an act of, after both the act (c) and the act (e) and before both the act (d) and the act (f), forming a second insulation film provided so as to cover the second surface of the semiconductor substrate, a sidewall of the through-hole, and a sidewall and a bottom of the recess, and selectively providing an opening over the bottom of the recess in the second insulation film.

According to this, a semiconductor device having the first and the second insulation films can be fabricated. As described above, with such a semiconductor device, leakage currents from the diffusion region can be prevented.

In addition, the method may include an act of providing a first insulation resin layer on the first surface of the semiconductor substrate so as to cover the first line, and selectively providing openings over the first line in the first insulation resin layer.

Moreover, the method may further include an act of forming external electrodes which are electrically connected to the first line, in the openings formed in the first insulation resin layer.

In addition, the method may include an act of forming a second insulation resin layer on the second surface of the semiconductor substrate.

Furthermore, the act of forming the second insulation resin layer is preferred to be performed substantially concurrently with the act (g). This can reduce the number of fabrication steps.

With the above-mentioned semiconductor device and the method for fabricating the same, superior electrical properties and high strength can be achieved, thereby providing advantages in miniaturization and thickness reduction, and also allowing for cost reduction.

### BRIEF DESCRIPTION OF THE DRAWINGS

FIGS. 1A and 1B are, respectively, a cross-sectional view and a perspective view of an example semiconductor device in accordance with the first embodiment of the present disclosure.

FIG. 2 is a cross-sectional view of an example semiconductor device in accordance with a variation of the first embodiment of the present disclosure.

FIGS. 3A and 3B are, respectively, a cross-sectional view and a perspective view of an example semiconductor device in accordance with the second embodiment of the present disclosure.

FIG. 4 is a cross-sectional view of an example semiconductor device in accordance with a variation of the second embodiment of the present disclosure.

FIG. 5 is a cross-sectional view illustrating a configuration of a semiconductor device as the Background Art.

### DETAILED DESCRIPTION

Example embodiments of the technologies of the present disclosure will be described below. Note that, here, a “vertical” PN diode is illustrated merely by way of example and is not intended to be limiting, and that vertical transistors such as power MOS and bipolar transistors provide the same or similar advantages.

### First Embodiment

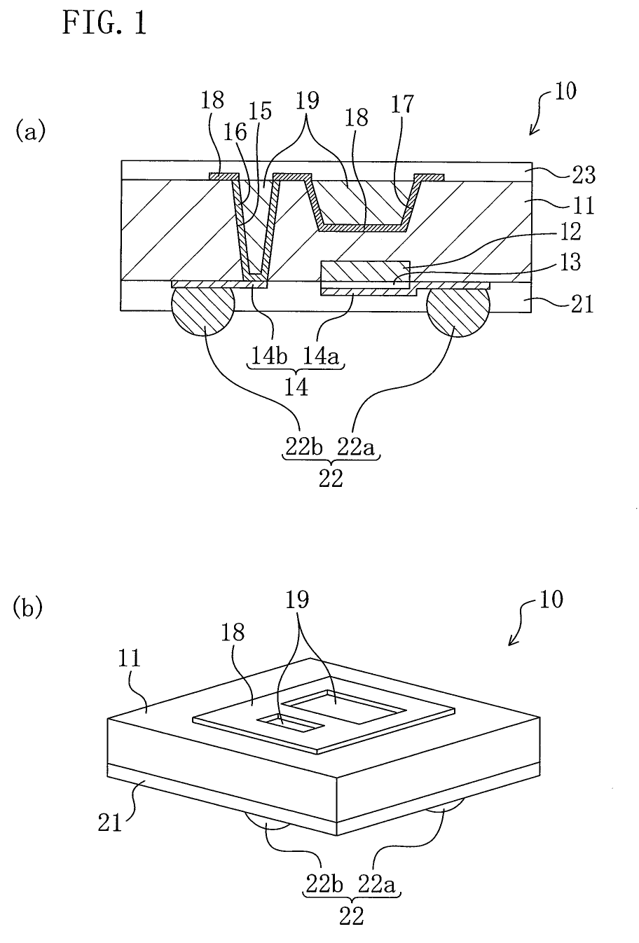

The first embodiment will now be described below. FIGS. 1A and 1B are, respectively, a cross-sectional view and a perspective view schematically illustrating a configuration of an example semiconductor device 10 of the first embodiment. Note that the second insulation resin layer 23 is not shown in FIG. 1B.

As shown in FIG. 1A, the semiconductor device 10 includes, for example, an n-type semiconductor element 11 configured using a semiconductor substrate. On a surface portion of a first surface (front surface, the lower surface as shown in the figure) of the semiconductor element 11, a diffusion region 12 of a different conductivity type from that of the semiconductor element 11 (here, p-type). Also, on the first surface, an electrode portion 13, which is electrically connected to the diffusion region 12 and is formed using metal such as Al and Cu as the main components, and a first metal line 14 are provided.

In this regard, the first metal line 14 is formed by plating with, for example, Cu or metal containing Cu as the main component. In addition, the first metal line 14 includes a first metal line segment 14a, which is electrically connected to the diffusion region 12 through the electrode portion 13, and another first metal line segment 14b, which is electrically connected to a portion of the first surface of the semiconductor element 11 other than the diffusion region 12.

Additionally provided is a through-hole 15 penetrating the semiconductor element 11 in the thickness direction thereof so as to reach the rear surface with respect to the first metal line segment 14b, which is electrically connected to the portion of the first surface of the semiconductor element 11 other than the diffusion region 12. The depth of the through-hole 15 is, for example, 10 μm-150 μm. Also provided is a through-hole electrode 16, formed in the through-hole 15, which is electrically connected to the first metal line segment 14b and extends to a second surface (rear surface, the upper surface as shown in the figure) of the semiconductor element 11.

A recess 17 is formed from the second surface of the semiconductor element 11 so as to locally thin the semiconductor element 11 in a portion immediately under the diffusion region 12. Also, a second metal line 18 is formed so as to extend from the inside of the recess 17 to the second surface of the semiconductor element 11. The second metal line 18 is electrically connected to the through-hole electrode 16 on the second surface of the semiconductor element 11.

Filling layers 19 are formed to fill the remaining space in the through-hole 15, in which the through-hole electrode 16 is formed, and in the recess 17, in which the second metal line 18 is formed. The filling layers 19 can be formed using resin or metal. When resin is used, the resin may be either conductive or non-conductive. When metal is used, the filling layers 19 may be formed by plating with, for example, metal containing Cu, Ti, and Ni as the main components.

In this regard, the thickness of the remaining portion of the semiconductor element 11 (n-type layer) immediately under the diffusion region 12 is determined by the depth of the recess 17. Since this portion serves as a resistor while the circuit is operating, this depth is a factor in determining a maximum current consumption. As such, in order to increase the maximum current consumption, it is essential, in terms of electrical properties, to reduce the thickness of the remaining portion of the semiconductor element 11 (n-type layer) immediately under the diffusion region 12 by increasing the depth of the recess 17 as much as practically possible. For example, it is preferable to reduce the thickness to less than or equal to 50 μm. Note that even if this is not achieved, any thickness reduction produces an effect accordingly.

The recess 17 is formed so as to avoid contact with a peripheral edge (lateral surface) of the semiconductor element 11. That is, the recess 17 is provided such that a portion (e.g., a box-shaped volume) is hollowed out from the second surface of the semiconductor element 11. With this configuration, any peripheral portion of the semiconductor element 11 is not thinned, but only a portion immediately under the diffusion region 12 is locally thinned by means of the recess 17. Due to this and also a configuration in which one of the filling layers 19 is formed in the recess 17, not only a superior electrical property (maximum current consumption) is provided, but also the bending strength is greater than that of a structure in which the semiconductor element is uniformly thinned. Since a support substrate for improving the bending strength is no longer required, this configuration is advantageous in thickness reduction of the semiconductor device 10, and also, costs can be reduced by reducing the number of fabrication steps for attachment process of a support substrate, material costs, etc.

A first insulation resin layer 21 is formed on the first surface of the semiconductor element 11 so as to cover the entire first surface of the semiconductor element 11 and the first metal line 14. Note that the first insulation resin layer 21 has openings selectively opened over the first metal line 14. In addition, the openings in the first insulation resin layer 21 include external electrodes 22 (22a and 22b) made of, for example, a lead-free solder material having a Sn—Ag—Cu composition; and the first metal line 14 and the external electrodes 22 are electrically connected to each other.

Formed on the second surface of the semiconductor element 11 is a second insulation resin layer 23 so as to cover the entire second surface of the semiconductor element 11, the through-hole electrode 16, the recess 17, and the second metal line 18. In this regard, the filling layers 19 filled in the recess 17, and the second insulation resin layer 23 may be formed using a same resin material and be formed substantially concurrently. In addition, as for the resin material used for the second insulation resin layer 23, it is preferred to use a light-blocking resin. This will prevent a photocurrent induced by light excitation on the semiconductor element 11 having a photoelectric effect, thereby preventing a malfunction of the semiconductor element 11 due to a photocurrent.

The diffusion region 12 is electrically connected to the external electrode 22a through the electrode portion 13 and the first metal line segment 14a. In addition, the portion of the semiconductor element 11 (n-type layer) locally thinned by the recess 17 under the diffusion region 12 is electrically connected to the external electrode 22b through the second metal line 18, the through-hole electrode 16, and the first metal line segment 14b. In this way, as for a device formed in a vertical configuration on the semiconductor element 11 (e.g., a PN diode), it is designed such that electrical signals can be output by means of the two external electrodes 22a and 22b, which are formed on a same surface (the first surface).

As described above, as for the semiconductor device 10 illustrated by way of example in FIGS. 1A and 1B, the semiconductor element 11 is locally thinned by providing the recess 17 from the second surface immediately under the diffusion region 12, thereby allowing the resistance while the circuit is operating to be decreased, and thus the maximum current consumption to be increased. In this regard, since the recess 17 is provided so as to avoid contact with a peripheral edge of the semiconductor element 11, and the recess 17 is filled with the filling layer 19, a significant decrease of the bending strength is prevented.

When the semiconductor device 10 is mounted on a printed board, etc., a mounter is operated such that the suction nozzle thereof makes contact with either the recess 17 and the filling layer 19, or the second insulation resin layer 23. In this way, stress during a contact with and a press by the suction nozzle can be reduced, thereby preventing mounting problems such as fracturing, chipping, and cracking from occurring on the semiconductor device 10.

That is, the semiconductor device 10 illustrated by way of example in this embodiment is superior both in electrical properties (e.g., maximum current consumption) and the bending strength compared to that of the Background Art. Moreover, since a support substrate for strength improvement is not essential, the semiconductor device 10 is also advantageous in thickness reduction, and the number of fabrication steps concerning the support substrate as well as material costs, etc., can be reduced.

Note that, as for the semiconductor device 10 illustrated by way of example in FIGS. 1A and 1B, the first insulation resin layer 21, the external electrodes 22, and the second insulation resin layer 23 are not essential components for the semiconductor device 10 to provide the advantages thereof, thus a configuration without these components is possible. However, considering reliability of mounting on a printed board, these components are preferred to be formed.

### Variation of the First Embodiment

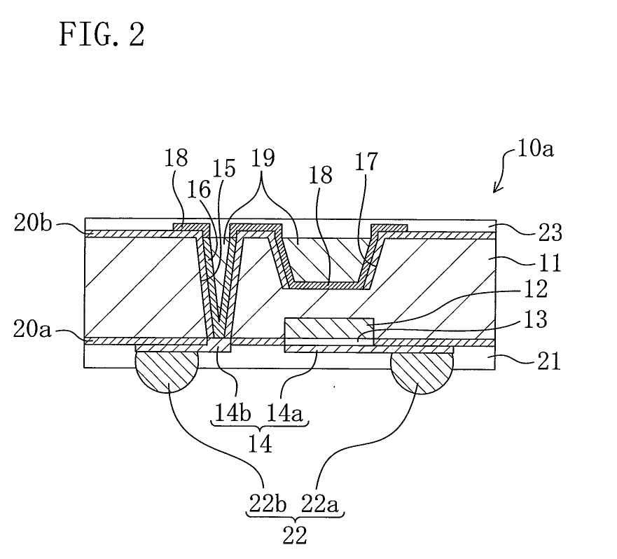

Next, a variation of the first embodiment will now be described. FIG. 2 is a cross-sectional view of an example semiconductor device 10a. With respect to the semiconductor device 10 as shown in FIG. 1A, the semiconductor device 10a further includes a first insulation film 20a and a second insulation film 20b. The other components are same or similar, and are designated, in FIG. 2, by like reference characters as those used in FIG. 1A.

The first insulation film 20a is made of, for example, SiO₂, SiN, etc., and is formed so as to cover the first surface of the semiconductor element 11. The second insulation film 20b is formed so as to cover the second surface of the semiconductor element 11, a sidewall of the through-hole 15, and a sidewall and a bottom of the recess 17.

Note that the first insulation film 20a has openings over the through-hole electrode 16 and over the diffusion region 12. Also, the second insulation film 20b has openings over the bottom of the recess 17 and in a portion where the second insulation film 20b would contact the first metal line 14 in the through-hole 15.

The first insulation film 20a and the second insulation film 20b prevent leakage currents (e.g., a leakage current from the diffusion region 12 to the through-hole electrode 16) from flowing, thereby ensuring that currents flow efficiently from the diffusion region 12 through the thinned portion of the semiconductor element 11 (n-type layer) immediately under the diffusion region 12 and through the bottom of the recess 17 to the second metal line 18. Currents further flow from the second metal line 18 to the through-hole electrode 16, and then through the opening portion of the first insulation film 20a at the bottom of the through-hole electrode 16 to the first metal line 14, which is electrically connected to the through-hole electrode 16.

As described above, with the semiconductor device 10a of this variation, leakage currents can be prevented, in addition to the same or similar advantages of the semiconductor device 10.

### Second Embodiment

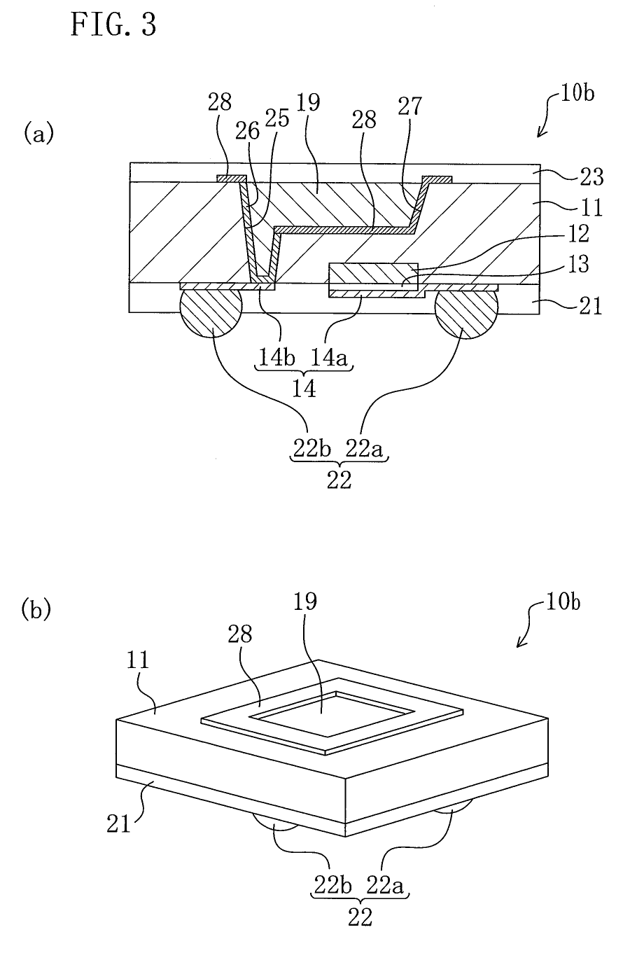

The second embodiment will now be described below. FIGS. 3A and 3B are, respectively, a cross-sectional view and a perspective view schematically illustrating a configuration of an example semiconductor device 10b of the second embodiment. Note that the second insulation resin layer 23 is not shown in FIG. 3B.

As shown in FIGS. 3A and 3B, the semiconductor device 10b includes a through-hole 25 with a through-hole electrode 26 and a recess 27 with a second metal line 28 collectively having a different configuration as compared with the example semiconductor device 10 of the first embodiment. The other components are same or similar, and are designated in FIGS. 3A and 3B by like reference characters as those used in FIGS. 1A and 1B.

As shown in FIG. 3A, in the example semiconductor device 10b of this embodiment, the through-hole 25 is disposed inside the recess 27, and is coupled therewith. As such, the through-hole electrode 26 on the sidewall of the through-hole 25 and the second metal line 28 in the recess 27 are coupled. This is the difference from the semiconductor device 10 of the first embodiment, in which the through-hole 15 and the recess 17 are separately formed. In addition, in the semiconductor device 10b, the filling layer 19 fills both the coupled through-hole 25 and recess 27.

With this configuration, the semiconductor device 10b provides the following advantages, in addition to those described with respect to the first embodiment.

In a case of the semiconductor device 10b, since the through-hole 25 and the through-hole electrode 26 are formed inside the recess 27, both the area and the depth to be filled are reduced as compared to the case of filling the filling layer 19 into the separate through-hole 15 as with the first embodiment. For example, as compared to the through-hole 15 having a depth corresponding to the thickness of the semiconductor element 11, the depth to be filled for the through-hole 25 is reduced by the depth of the recess 27. As a result, filling capability of the filling layer 19 is improved, thereby preventing problems such as voids and unfilled portions from occurring.

In addition, since the recess 27 is formed so as to include the through-hole 25, the recess 27 is larger than that of the first embodiment. This point is advantageous in improvement in filling capability. Also, an increase of the amount of the filling layer 19 in itself can contribute to improving the strength.

Moreover, since the through-hole electrode 26 is formed inside the recess 27, the wiring path from a bottom of the recess 27 through the second metal line 28 and the through-hole electrode 26 to the first metal line segment 14b is shorter compared to the case of the first embodiment. Thus, the wiring resistance of this wiring path can be reduced, and even higher currents can be handled compared to the case of the first embodiment.

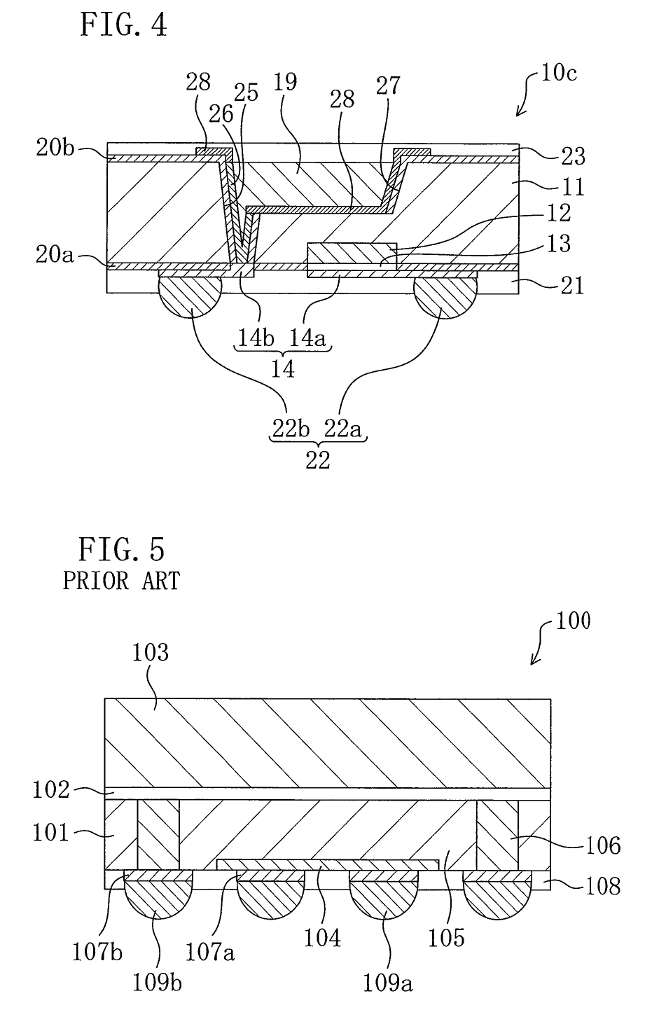

Note that, as with the above-mentioned variation of the first embodiment, a first insulation film 20a covering the first surface of the semiconductor element 11 may be provided, and a second insulation film 20b covering the second surface of the semiconductor element 11, a sidewall of the through-hole 25, and a sidewall and a bottom of the recess 27 may be provided. An example of this case is shown as a semiconductor device 10c in FIG. 4. The first insulation film 20a and the second insulation film 20b prevent leakage currents (e.g., a leakage current from the diffusion region 12 to the through-hole electrode 26) from flowing.

### Method for Fabricating Example Semiconductor Devices of Respective Embodiments

A method for fabricating semiconductor devices will now be described below. First, the example semiconductor device 10 of the first embodiment will be described, and then the differences with the other semiconductor device 10a, semiconductor device 10b, and semiconductor device 10c will be described.

Note that a “vertical” PN diode is also illustrated here by way of example and is not intended to be limiting, and that vertical transistors such as power MOS and bipolar transistors may be used.

Description is provided with reference to FIGS. 1A and 1B. Firstly, a wafer including a plurality of the semiconductor elements 11 is prepared. Each semiconductor element 11 is formed using a known method, and is assumed to include, for example, a p-type diffusion region 12 provided on a surface portion of a first surface of the semiconductor element 11, which is n-type, and an electrode portion 13 provided on the first surface of the semiconductor element 11. The electrode portion 13 is made using metal such as Al and Cu as the main components. It is preferable that the thickness of the wafer be reduced beforehand to a desired value (typically about 100-300 μm) by back-grinding, and a mirror polishing process such as a CMP (Chemical Mechanical Polishing) process be further applied.

Next, a first metal line 14 is formed on the first surface of the semiconductor element 11. More specifically, first of all, a metal film is formed over the entire first surface of the semiconductor element 11 using a sputtering method, etc. In this regard, Ti, TiW, Cr, Cu, etc., are mainly used for the metal film. Then, a photosensitive liquid resist is coated by applying a dry film, spin-coating, etc. Following this, using a photolithography technique, the resist is patterned so that the portions where the first metal line 14 needs to be formed will be opened by exposure and development. Note that the thickness of the resist can be determined according to the thickness of the first metal line 14 to be eventually formed. It is typically about 5-30 μm.

After this, metal line segments are formed in the openings, provided in the resist, using an electrolytic plating process, then the resist is removed and cleaned. Thereafter, the portion of the metal film other than the portion where the metal line is formed using the electrolytic plating process is removed by wet etching, then the first metal line 14 is formed.

Note that the resist and the dry film may be of either negative type or positive type. As the electrolytic plating process, Cu plating is mainly employed. In the wet etching process of the metal film, a hydrogen peroxide solution is used for a Ti film, while ferric chloride is used for a Cu film.

Note that even though an additive process using an electrolytic plating process is herein described, it is to be understood that other methods may also be used. For example, but not by way of limitation, the first metal line 14 may be formed by performing an electrolytic Cu plating over the entire first surface of the semiconductor element 11, and then performing resist formulation and wet etching.

Thereafter, a through-hole 15 penetrating the semiconductor element 11 in the thickness direction thereof so as to reach the rear surface of the first metal line segment 14b, and a recess 17 to locally thin a portion immediately under the diffusion region 12 are formed from the second surface side of the semiconductor element 11. More specifically, a dry etching, wet etching, etc., can be performed using a resist, SiO₂, metal film, etc., as a mask.

In this regard, since the depths and the opening areas of the through-hole 15 and the recess 17 are significantly different, it is preferable to form these components separately. Either may be formed first.

According to the foregoing, by locally thinning the semiconductor element 11 (n-type layer) in a portion immediately under the diffusion region 12 by means of the recess 17, a structure which can decrease the resistance while the circuit is operating and can increase the maximum current consumption can be obtained.

After this, a through-hole electrode 16, which is provided inside the through-hole 15 so as to extend from the inside of the through-hole 15 to the second surface of the semiconductor element 11, and a second metal line 18, which is provided inside the recess 17 and is electrically connected to the through-hole electrode 16 are formed. In this regard, it is preferable that the through-hole electrode 16 and the second metal line 18 be formed substantially concurrently. More specifically, first, a metal film is formed over the entire second surface of the semiconductor element 11, the inside of the through-hole 15, and the inside of the recess 17 using a sputtering method, etc., in a similar way to the method for forming the first metal line 14. Next, the metal film is patterned to form the through-hole electrode 16 and the second metal line 18 by performing photolithography, electrolytic plating, wet etching, etc. Also, the through-hole electrode 16 and the second metal line 18 may be formed separately.

Following this, filling layers 19 are formed in the remaining space in the recess 17, in which the second metal line 18 is formed, and in the remaining space in the through-hole 15, in which the through-hole electrode 16 is formed. As the filling material, resin or metal may be used.

If metal is used for filling, metal plate can be used to fill using electrolytic plating, or metallic paste can principally be used to fill using a printing process, dipping, etc.

If electrolytic plating is used for filling, it is preferable that formation of the through-hole electrode 16 and the second metal line 18 be performed substantially concurrently. On doing this, the filling layers 19 are formed so as to fill in the through-hole 15 and the recess 17 entirely, and the second metal line 18 and the through-hole electrode 16 are formed monolithically.

In addition, when the filling layers 19, and the through-hole electrode 16 and the second metal line 18 are formed separately, for example, after forming the through-hole electrode 16 and the second metal line 18, a mask having openings in the portions corresponding to the through-hole 15 and the recess 17 is formed, and then the filling layers 19 are formed in the through-hole 15 and the recess 17 using an electrolytic plating process.

If resin material is used for filling, a light-curing or heat-curing liquid resin can be used to fill by spin-coating, or resin paste can be used to fill using a printing process, dipping, etc.

According to the foregoing, the recess 17 does not make contact with a peripheral edge of the semiconductor element 11. That is, the structure will be such that a portion (e.g., a box-shaped volume) is hollowed out from the second surface of the semiconductor element 11. Since any peripheral portion including the lateral surface of the semiconductor element 11 is not thinned, and the filling layers 19 are provided as well, a significant decrease of the bending strength is prevented from being caused.

After this, a first insulation resin layer 21 is formed on the first surface of the semiconductor element 11 so as to cover the first metal line 14. For example, the first insulation resin layer 21 is formed using a photosensitive resin and by spin-coating or applying a dry film. Next, using a photolithography technique, openings for exposing portions of the first metal line 14 is formed by selectively removing the first insulation resin layer 21.

Following this, external electrodes 22 for electrical connection to the first metal line 14 are formed using a solder ball attachment process with flux, a solder paste printing process, or an electrolytic plating process to the openings provided over the first metal line 14. As the material, for example, a lead-free solder material having a Sn—Ag—Cu composition may be used.

Next, a second insulation resin layer 23 is formed on the second surface of the semiconductor element 11 so as to cover the through-hole electrode 16 and the second metal line 18. For example, a light-curing or heat-curing liquid resin is spin-coated. Alternatively, a process in which a light-curing or heat-curing resin in a film form is applied may be used. Note that the second insulation resin layer 23 may be formed substantially concurrently with the filling layers 19 using a same resin material.

After this, the wafer including the plurality of the semiconductor elements 11 is cut and separated (diced) for a plurality of the semiconductor devices 10 using cutting means such as a dicing saw.

The semiconductor device 10 is thus fabricated. That is, it is possible to fabricate semiconductor devices which are advantageous both in miniaturization and thickness reduction because the semiconductor device 10 is superior both in electrical properties (e.g., maximum current consumption) and the bending strength compared to the semiconductor device of the Background Art, and also because a support substrate for strength improvement is not required, and which allows for cost reduction because attachment process, material costs, etc., with respect to the support substrate are no longer required.

There has thus been described a method for fabricating an individual wafer including a plurality of the semiconductor elements 11. However, it is possible to use a fabrication method in which a substrate for support is attached beforehand, as a reinforcing member for a wafer, on the first surface side or the second surface side of the semiconductor element 11, and is detached in a later process.

Next, differences in the fabrication methods will be described with respect to the other examples of the semiconductor devices.

First, as for the semiconductor device 10b illustrated in FIGS. 3A and 3B, the through-hole 25 is disposed inside the recess 27. To this end, for example, after the recess 27 has been formed, a resist, SiO₂, metal film, etc., is formed as a new mask, then the through-hole 25 is formed inside the recess 27. Alternatively, the method may be such that after the through-hole 25 has been formed, a mask is newly formed, then the recess 27 is formed in a portion including the through-hole 25.

Next, cases for the semiconductor device 10a illustrated in FIG. 2 and the semiconductor device 10c illustrated in FIG. 4 will be described. These semiconductor devices further include a first insulation film 20a and a second insulation film 20b in addition to the components of the semiconductor device 10 and the semiconductor device 10b, respectively.

The first insulation film 20a is formed, before the step of forming the first metal line 14, using a CVD process, an insulating-paste printing process, etc. The second insulation film 20b is formed, after the formation of both the through-hole 15 and the recess 17 and before the formation of the second metal line 18, also using a CVD process, an insulating-paste printing process, etc. Following this, the second insulation film 20b is removed and openings are formed over a bottom of the through-hole 15 (the connecting portion to the first metal line segment 14b) and over the bottom of the recess 17. To this end, a dry etching, wet etching, etc., can be performed using a resist, SiO₂, metal film, etc., as a mask.

Even though the description above is all provided assuming that the conductivity type of the semiconductor element 11 is n-type, and that the conductivity type of the diffusion region 12 is p-type, the conductivity type of the semiconductor element 11 may be p-type and the conductivity type of the diffusion region 12 may be n-type, on the contrary.

In addition, a vertical PN diode has been described above as an example. However, it is not intended to limit the present invention to this, but the described configuration may also be applied, for example, to a bipolar transistor. In this case, a diffusion layer, etc., is formed in a portion locally thinned by the recess 17, and a vertical PNP or NPN structure is provided. With this structure, each advantage already described can be achieved; for example, a resistance in a vertical direction while the circuit is operating is reduced by the amount corresponding to the thickness reduction, thus a maximum current consumption can be increased.

As another example, in a case of a power MOS also, it is possible to form a gate/source layer, a drain layer, etc., in a portion thinned by the recess 17, and to provide a structure of a vertical element. Moreover, the described structure can be applied to various types of vertical elements.

In addition, although the first metal line 14 (14a, 14b) and the second metal lines 18 and 28 have been described in the above description, other types of lines made of, for example, a conductive paste, a conductive polymer, etc., may be used.

As for a formation method for conductive pastes, a screen-printing process, an inkjet printing process, etc., can be selected appropriately.

As for a formation method for conductive polymers, vacuum process in which gaseous conductive polymer is deposited on a substrate, wet process which allows conductive polymer to grow on a substrate in a self-organizing manner in a liquid, etc., can be selected as appropriate.

The semiconductor devices and the method for fabricating the same described above can achieve a CSP which is superior both in electrical properties and bending strength, advantageous both in miniaturization and thickness reduction, and allows for cost reduction; and therefore, is also useful for miniaturization, thickness reduction, weight reduction, and performance improvement of various electronic devices.

What is claimed is:

1. A semiconductor device, comprising:
a semiconductor substrate having a first surface and a second surface opposite the first surface;
a diffusion region provided on a surface portion of the first surface;
a first line provided on the first surface;
a through-hole penetrating the semiconductor substrate in the thickness direction;
a through-hole electrode provided in the through-hole, and contacting a rear surface of the first line and extending to the second surface;
a recess provided on the second surface; and
a second line provided in the recess and electrically connected to the through-hole electrode,
wherein
a part of the first line is electrically connected to the diffusion region.

2. The semiconductor device of claim 1, comprising:
an electrode portion provided on the diffusion region.

3. The semiconductor device of claim 1, comprising:
filling layers filling the through-hole and the recess.

4. The semiconductor device of claim 3, wherein
the filling layers are made of resin or metal.

5. The semiconductor device of claim 1, wherein
the first line is electrically connected to the diffusion region through the electrode portion.

6. The semiconductor device of claim 1, wherein
the recess is formed so as to avoid contact with a peripheral edge of the semiconductor substrate.

7. The semiconductor device of claim 1, wherein
the recess is formed in the opposite side of the diffusion region.

8. The semiconductor device of claim 1, wherein
the through-hole is disposed in the recess.

9. The semiconductor device of claim 1, comprising:
a first insulation film covering the first surface of the semiconductor substrate; and
a second insulation film covering the second surface of the semiconductor substrate, a sidewall of the through-hole, and a sidewall and a bottom of the recess,
wherein
the fist insulation film has an opening selectively provided over the diffusion region, and
the second insulation film has an opening selectively provided over the bottom of the recess.

10. The semiconductor device of claim 1, comprising:
a first insulation resin layer provided on the first surface of the semiconductor substrate so as to cover the first line,
wherein
the first insulation resin layer has openings selectively provided over the first line.

11. The semiconductor device of claim 10, wherein
the openings provided in the first insulation resin layer include external electrodes which are electrically connected to the first line.

12. The semiconductor device of claim 1, comprising:
a second insulation resin layer on the second surface of the semiconductor substrate.

13. The semiconductor device of claim 12, comprising:
filling layers filling the through-hole and the recess, wherein
the second insulation resin layer is formed of a same resin material as that of the filling layers.

14. The semiconductor device of claim 12, wherein
the second insulation resin layer is formed of a light-blocking resin.

15. A method for fabricating a semiconductor device comprising acts of:
(a) preparing a semiconductor substrate including a diffusion region provided on a surface portion of a first surface;
(b) forming a first line on the first surface;
(c) forming a through-hole penetrating the semiconductor substrate in the thickness direction;
(d) forming a through-hole electrode, in the through-hole, extending from a rear surface of the first line to a second surface of the semiconductor substrate;
(e) forming a recess on the second surface; and
(f) forming a second line, in the recess, electrically connected to the through-hole electrode,
wherein
a part of the first line is electrically connected to the diffusion region.

16. The method for fabricating a semiconductor device of claim 15, comprising an act of:
(g) after the act (d) and the act (f), forming filling layers filling the through-hole and the recess.

17. The method for fabricating a semiconductor device of claim 15, wherein
the act (c) is performed after the act (e), and
in the act (c), the through-hole is formed in the recess.

18. The method for fabricating a semiconductor device of claim 15, wherein
the act (c) is performed before the act (e), and
in the act (e), the recess is formed so as to include the through-hole.

19. The method for fabricating a semiconductor device of claim 15, wherein
the act (d) and the act (f) are performed substantially concurrently.

20. The method for fabricating a semiconductor device of claim 15, further comprising acts of:
forming a first insulation film, which covers the first surface of the semiconductor substrate, and selectively providing an opening over the diffusion region in the first insulation film; and
after both the act (c) and the act (e) and before both the act (d) and the act (f), forming a second insulation film provided so as to cover the second surface of the semiconductor substrate, a sidewall of the through-hole, and a sidewall and a bottom of the recess, and selectively providing an opening over the bottom of the recess in the second insulation film.

21. The method for fabricating a semiconductor device of claim 15, comprising an act of:
providing a first insulation resin layer on the first surface of the semiconductor substrate so as to cover the first line, and selectively providing openings over the first line in the first insulation resin layer.

22. The method for fabricating a semiconductor device of claim 21, further comprising an act of:
forming external electrodes which are electrically connected to the first line in the openings formed in the first insulation resin layer.

23. The method for fabricating a semiconductor device of claim 15, further comprising an act of:
forming a second insulation resin layer on the second surface of the semiconductor substrate.

24. The method for fabricating a semiconductor device of claim 23, wherein
the act of forming the second insulation resin layer is performed substantially concurrently with the act (g).
